(19) United States
(12) Patent Application Publication
(10) Pub. No.: US 2009/0153168 A1
(43) Pub. Date: Jun. 18, 2009

(54) HI-FIX BOARD, TEST TRAY, TEST HANDLER, AND METHOD FOR MANUFACTURING PACKAGED CHIPS

(76) Inventors: Hee Rak Beom, Seoul (KR); Yong Geun Park, Asan-si (KR)

Correspondence Address: KED & ASSOCIATES, LLP, P.O. Box 221200, Chantilly, VA, 20153-1200, US

(21) Appl. No.: 12/327,853

(22) Filed: Dec. 4, 2008

(30) Foreign Application Priority Data
Dec. 13, 2007 (KR) 10-2007-0129540

(51) Int. Cl. G01R 31/02; G01R 31/28; H01L 21/673

(52) U.S. Cl. 324/755; 324/158.1; 438/17; 414/222.01; 257/E21.521

(57) ABSTRACT

A hi-fix board, a test tray, a test handler, and a packaged chip manufacturing method are provided. The hi-fix board includes: test sockets to which packaged chips to be tested are connected; and a main frame in which the test sockets are disposed in at least one first area to form an a×b matrix (where a and b are integers greater than 0) and the test sockets are disposed in at least one second area to form a c×d matrix (where c is an integer greater than a and d is an integer greater than 0). By allowing the test tray to contain more packaged chips at a time and minimizing a difference in length between a horizontal direction and a vertical direction, it is possible to reduce the index time. By allowing all the packaged chips contained in a test tray to be subjected to a testing process at the same time, it is possible to reduce the time for the testing process and to enhance the stability.

### BACKGROUND

1. Technical Field

The present invention relates to a test handler for connecting packaged chips to be tested to a tester and classifying packaged chips tested by the tester by grades on the basis of the test result.

2. Description of Related Art

A test handler may be used to perform electrical tests on packaged chips at the conclusion of a packaging process.

The test handler performs a loading process, an unloading process, and a testing process by the use of a test tray including plural containing units containing the packaged chips.

In the loading process, the packaged chips to be tested are picked up from a user tray containing the packaged chips and are contained in the test tray. The loading process is performed by a picker system having nozzles that can suck and fix the packaged chips.

In the unloading process, tested packaged chips are separated from the test tray and the separated packaged chips are contained in user trays located at different positions on the basis of the test result. The unloading process is performed by the picker system.

In the testing process, the packaged chips contained in the test tray are connected to a tester. The tester includes a hi-fix board to which the packaged chips to be tested are connected and serves to test the packaged chip to determine electrical characteristics of the packaged chips connected to the hi-fix board.

FIG. 1 is a diagram schematically illustrating a tester and a path through which a test tray moves in a chamber system disposed in the test handler. Reference numerals denoting the test trays in FIG. 1 indicate a configuration of the test handler at which the test trays are located.

Referring to FIG. 1, a chamber system 100 disposed in the test handler includes a first chamber 101, a second chamber 102, and a third chamber 103 so as for the tester 200 to test packaged chips under environments of high temperature and low temperature as well as normal temperature.

The first chamber 101 heats or cools the packaged chips contained in a test tray T while allowing the test tray T to move therein. The packaged chips to be tested is adjusted to a temperature range (hereinafter, referred to as “testing temperature”) in which the packaged chips should be tested by the tester 200. The test tray T located in the first chamber 101 is a test try T transferred from a structure for performing the loading process.

When the packaged chips are adjusted to the testing temperature, the test tray T is transferred from the first chamber 101 to the second chamber 102.

In the second chamber 102, the packaged chips adjusted to the testing temperature are connected to the hi-fix board 201. The second chamber 102 is provided with a contact unit (not shown) for connecting the packaged chips adjusted to the testing temperature to the hi-fix board 201.

The hi-fix board 201 is inserted into the second chamber 102. The hi-fix board 201 includes plural test sockets 201a to which the packaged chips to be tested are connected. The plural test sockets 201a are disposed in the hi-fix board 201 to form a matrix.

When the packaged chips are tested, the test tray T is transferred from the second chamber 102 to the third chamber 103.

In the third chamber 103, the tested packaged chips contained in the test tray T are restored to the normal temperature while allowing the test tray T to move therein. When the packaged chips are restored to the normal temperature or a temperature close to the normal temperature, the test tray T is transferred from the third chamber 103 to a structure for performing the unloading process.

The test tray T transferred in the chamber system 100 includes plural containing units C containing the packaged chips. The containing units C are disposed to form an m×n matrix (where m and n are integers greater than 0) corresponding to an m×n matrix of the test sockets 201a. That is, the containing units C and the test sockets form the same matrix.

The test handler has been developed to perform the loading process, the testing process, and the unloading process on many packaged chips for a short time so as to strengthen competitive power of products such as cost reduction of the packaged chips.

In the handler, it is intended to connect more packaged chips to the hi-fix board 201 at a time by containing more packaged chips in a single test tray T.

Accordingly, the test tray T includes more containing units C and the hi-fix board 201 includes more test sockets 201a.

The containing units C are arranged in a matrix as described above and the same number of containing units as the number of packaged chips connected to the hi-fix board 201 at a time can arranged in an m×n matrix.

For example, when the test tray T is embodied to contain 32 packaged chips, the matrix of the containing units C may be a 4×8 or 8×4 matrix. When the test tray T is embodied to contain 128 packaged chips, the matrix of the containing units C may be an 8×16 or 16×18 matrix.

Accordingly, the test tray T cannot help being formed longitudinal in a direction in which more containing units C are disposed among rows and columns, that is, in one direction of a horizontal direction (L) and a vertical direction (H). When the test tray T is formed longitudinal in one direction of the horizontal direction L or the vertical direction H, the following problems are caused.

First, when the test tray T is formed longitudinal in the horizontal direction L, the size in the horizontal direction 100L of the chamber system 100 is increased. When the test tray T is formed longitudinal in the vertical direction H, the height 100H of the chamber system 100 is increased. Accordingly, the size of the test handler may depart from the standard determined depending on an installation area.

Second, when the test tray T is formed longitudinal in the horizontal direction L, a transfer distance of the test tray T is increased. Accordingly, the time for the testing process cannot be reduced much due to the increase in index time. The index time means a time period from a time point when the packaged chips contained in a test tray T are connected to the hi-fix board 201 to a time point when the packaged chips contained in another test tray T are connected to the hi-fix board 201.

Third, in order to perform the testing process on all the packaged chips contained in the test tray T, the test tray T should move toward the hi-fix board 201 by a constant distance from the entire surface thereof. However, when the test tray T is formed longitudinal in one direction of the horizontal direction L and the vertical direction H, it is difficult to allow the test tray T to move by a constant distance from the entire surface thereof.

Fourth, when the test tray T is embodied to contain 512 packaged chips, the matrix of the containing units C may be a 32×16 or 16×32 matrix. Accordingly, the above-mentioned problems may become more severe as the test tray T contains more packaged chips.

### SUMMARY OF THE INVENTION

The invention is contrived to solve the above-mentioned problems. An advantage of some aspects of the invention is that it provides a test tray and a hi-fix board capable of containing more packaged chips and stabilizing a testing process without greatly enhancing the index time.

Another advantage of some aspects of the invention is that it provides a test handler satisfying a standard determined depending on an installation area even when a test tray is embodied to contain more packaged chips to reduce the time for a testing process.

Another advantage of some aspects of the invention is that it provides a method of manufacturing a packaged chip, which can strengthen competitive power of products such as cost reduction of the packaged chips by reducing the time for a testing process.

To accomplish the above-mentioned advantages, the invention may provide the following aspects.

According to an aspect of the invention, there is provided a hi-fix board including: test sockets to which packaged chips to be tested are connected; and a main frame in which the test sockets are disposed in at least one first area to form an a×b matrix (where a and b are integers greater than 0) and the test sockets are disposed in at least one second area to form a c×d matrix (where c is an integer greater than a and d is an integer greater than 0).

According to another aspect of the invention, there is provided a hi-fix board including: test sockets to which packaged chips to be tested are connected; and a main frame in which the test sockets are arranged in a first area including at least one row and a second area including the other rows. Here, the number of test sockets disposed in each row of the second area in the main frame is greater than the number of test sockets in each row of the first area.

According to another aspect of the invention, there is provided a test tray including: containing units containing packaged chips; and a tray frame in which the containing units are disposed in at least one first containing area to contain the packaged chips in an a×b (where a and b are integers greater than 0) matrix and are disposed in at least one second containing area to contain the packaged chips in a c×d (where d is an integer greater than a and d is an integer greater than 0) matrix.

According to another aspect of the invention, there is provided a test tray including: containing units containing packaged chips; and a tray frame in which the containing units are disposed in a first containing area forming at least one row and in a second containing area forming the other rows. Here, the containing units are disposed in the tray frame so as to contain the packaged chips, which are more than the packaged chips in each row of the first containing area, in each row of the second containing area.

According to another aspect of the invention, there is provided a test handler including: a loading unit containing the packaged chips to be tested in the test tray located in a loading position; a chamber system adjusting the packaged chips to be tested in the test tray to a testing temperature, connecting the packaged chips adjusted to the testing temperature to a hi-fix board, and restoring the tested packaged chips to a normal temperature; an unloading unit disposed aside the loading unit so as to classify the tested packaged chips contained in the test tray located in an unloading position on the basis of the test result; and a transferring unit transferring the test tray among the loading position, the chamber system, and the unloading position.

According to another aspect of the invention, there is provided a packaged chip manufacturing method including the steps of: preparing packaged chips to be tested; containing the prepared packaged chips in a test tray located at a loading position; adjusting the packaged chips contained in the test tray to a testing temperature; connecting the packaged chips contained in the test tray and adjusted to the testing temperature to a hi-fix board; restoring the tested packaged chips contained in the test tray to a normal temperature; and classifying the tested packaged chips contained in the test tray located at an unloading position on the basis of the test result.

### BRIEF DESCRIPTION OF THE DRAWINGS

FIG. 1 is a diagram schematically illustrating a tester and a path through which a test tray is transferred in a chamber system disposed in a test handler.

FIG. 2 is a diagram schematically illustrating a tray frame and containing units of a test tray according to an embodiment of the invention.

FIGS. 3 to 5 are front views schematically illustrating modified examples of the test tray according to the embodiment of the invention.

FIG. 6 is a perspective view schematically illustrating a tester and a hi-fix board disposed in the tester according to an embodiment of the invention.

FIGS. 7 to 9 are front views schematically illustrating modified examples of the hi-fix board according to the embodiment of the invention.

FIG. 10 is a plan view schematically illustrating a test handler according to an embodiment of the invention.

FIG. 11 is a diagram schematically illustrating a hi-fix board and a path through which the test tray is transferred in the chamber system of the test handler according to the embodiment of the invention.

### DESCRIPTION OF EXEMPLARY EMBODIMENTS

Hereinafter, a test tray according to an exemplary embodiment of the invention will be described in detail with reference to the accompanying drawings.

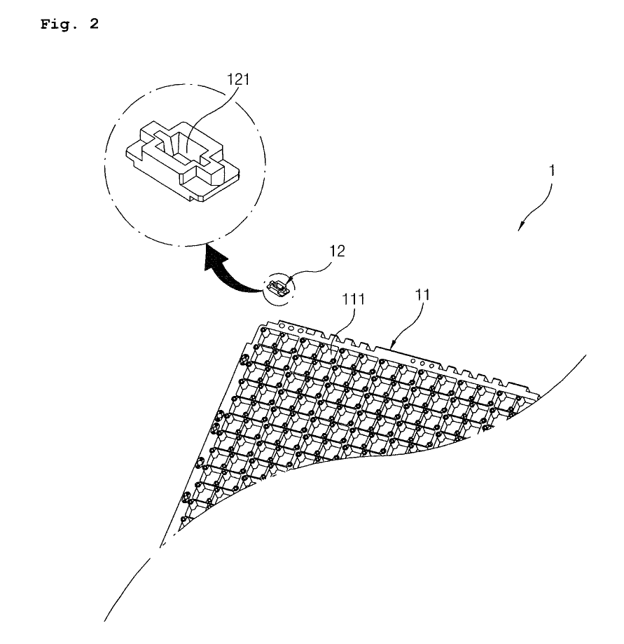

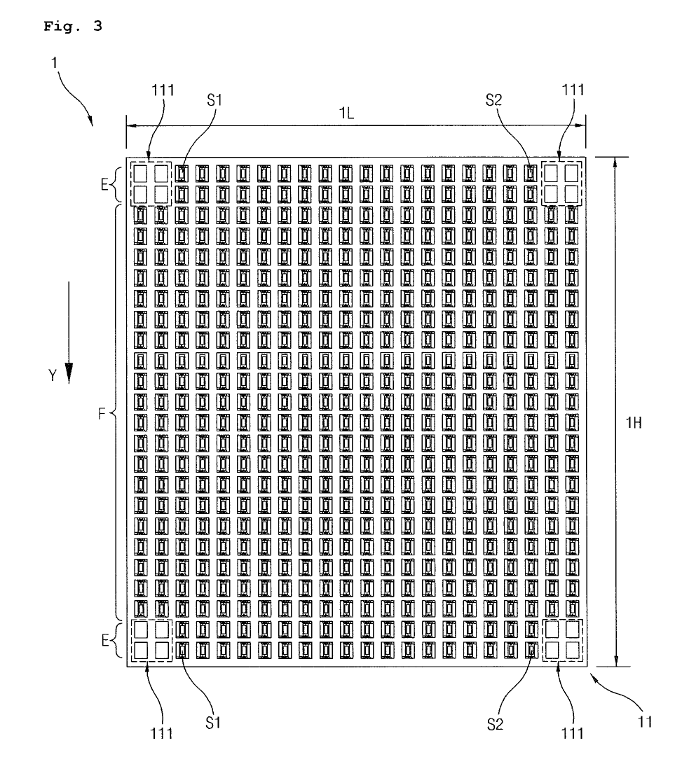

FIG. 2 is a diagram schematically illustrating a tray frame and containing units of a test tray according to an embodiment of the invention FIGS. 3 to 5 are front views schematically illustrating modified examples of the test tray according to the embodiment of the invention.

Referring to FIG. 2, the test tray 1 according to an embodiment of the invention includes a tray frame 11 and containing units 12.

The tray frame 11 is formed of a metal material excellent in thermal resistance in a rectangular plate shape.

Referring to FIGS. 2 and 3, the containing units 12 may be disposed in the tray frame 11 so as to contain packaged chips in an a×b (where a and b are integers greater than 0) matrix in at least one first containing area E and to contain the packaged chips in an c×d (where c is an integer greater than a and d is an integer greater than 0) matrix in at least one second containing area F.

The test tray 1 can contain the packaged chips in different matrixes in the first containing area E and the second containing area F so as to minimize a difference between the length 1L in a horizontal direction and the length 1H in a vertical direction.

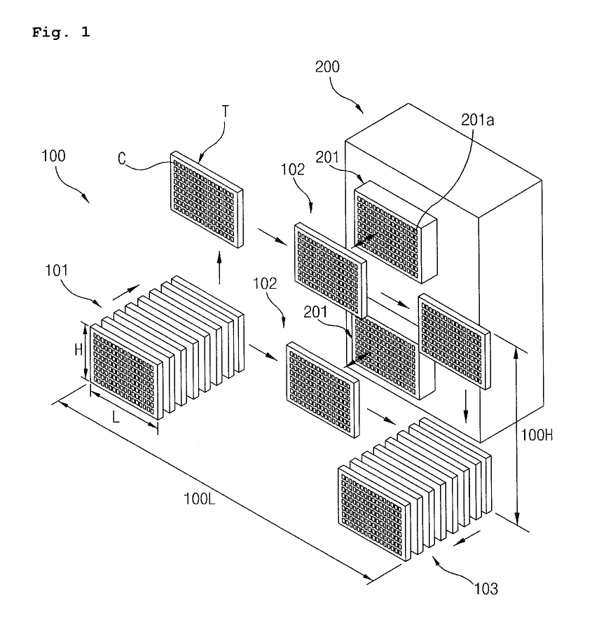

Accordingly, the test tray 1 according to the embodiment of the invention can solve the problem that the test tray T (see FIG. 1) according to the related art is formed longitudinal in one direction of the horizontal direction L (see FIG. 1) and the vertical direction H (see FIG. 1) due to containing the packaged chips to form one matrix.

Therefore, it is possible to allow the size of the test handler to satisfy the standard determined depending on the installation area, to reduce the index time, and to easily transfer the test tray 1 by a uniform distance from the entire surface so as to perform a testing process on all the packaged chips contained in the test tray.

The area of the tray frame 11 in which the containing units 12 are disposed forms a c×(b+d) matrix. The c×(b+d) matrix may be one of a 22×24 matrix, a 24×22 matrix, a 20×26 matrix, a 26×20 matrix, and a 23×23 matrix. In this area, the containing units 12 can be disposed in the tray frame 11 so as to contain 512 packaged chips.

When each containing unit 12 can contain two or more packaged chips, the number of containing units equal to or greater than the number of containing units capable of 512 packaged chips can be disposed in the tray frame 11.

When each containing unit 12 can contain one packaged chip, 512 or more containing units 12 can be disposed in the tray frame 11.

As shown in FIG. 3, when the areas of the tray frame 11 in which the containing units 12 can be disposed form a 22×24 matrix, only 512 containing units 12 can be disposed. Accordingly, the containing units 12 may not be disposed in the area in which 16 containing units 12 can be disposed among the areas of the tray frame 11 in which 528 containing units 12 in total can be disposed. The same is true when the areas of the tray frame 11 in which the containing units 12 can be disposed form a 24×22 matrix.

Although not shown, when the areas of the tray frame 11 in which the containing units 12 can be disposed form a 20×26 or 26×20 matrix, only 512 containing units 12 can be disposed. Accordingly, the containing units 12 may not be disposed in the area in which 8 containing units 12 can be disposed among the areas of the tray frame 11 in which 520 containing units 12 in total can be disposed.

Although not shown, when the areas of the tray frame 11 in which the containing units 12 can be disposed form a 23×23 matrix, only 512 containing units 12 can be disposed. Accordingly, the containing units 12 may not be disposed in the area in which 17 containing units 12 can be disposed among the areas of the tray frame 11 in which 529 containing units 12 in total can be disposed.

Therefore, the test tray 1 can be embodied to contain 512 packaged chips while minimizing the difference between the length 1L in the horizontal direction and the length 1H in the vertical direction.

Plural holes 111 forming a c×(b+d) matrix can be formed in the tray frame 11. The containing units 12 can be disposed in the tray frame 11 to communicate with the holes 111. The packaged chips can be contained in the containing units 12 or separated from the containing units 12 through the holes 111.

Plural holes 111 forming a 22×24 matrix or a 24×22 matrix may be formed in the tray frame 11. In this case, when the containing units 12 are disposed in the tray frame 11 to contain 512 packaged chips, 16 or fewer holes 111 are empty.

Plural holes 111 forming a 20×26 matrix or a 26×20 matrix may be formed in the tray frame 11. In this case, when the containing units 12 are disposed in the tray frame 11 to contain 512 packaged chips, 8 or fewer holes 111 are empty.

Plural holes 111 forming a 23×23 matrix may be formed in the tray frame 11. In this case, when the containing units 12 are disposed in the tray frame 11 to contain 512 packaged chips, 17 or fewer holes 111 are empty.

Although not shown, the tray frame 11 can be formed to have only the same number of holes 111 as the packaged chips that can be contained by the containing units.

In the tray frame 11, the containing units 12 can be disposed in a first containing area E including at least one row and can be disposed in a second containing area F including the other rows. The containing units 12 can be disposed in the tray frame 11 so as to contain different numbers of packaged chips in each row of the first containing area E and each row of the second containing area F.

That is, the containing units 12 can be disposed in the tray frame 11 so that the packaged chips form at least two different matrixes.

Accordingly, the test tray 1 according to the embodiment of the invention can solve the problem that the test tray T (see FIG. 1) according to the related art is formed longitudinal in one direction of the horizontal direction L (see FIG. 1) and the vertical direction H (see FIG. 1) due to containing the packaged chips to form one matrix. Therefore, the test tray 1 according to the embodiment of the invention can be manufactured to minimize the difference between the length 1L in the horizontal direction and the length 1H in the vertical direction.

Referring to FIGS. 2 and 3, each containing unit 12 includes a containing groove 121 in which a packaged chip is contained. The containing units 12 are disposed in the tray frame 11 so that the containing grooves 121 communicate with the holes 111 formed in the tray frame 11. The packaged chip can be contained in the containing units 12 or separated from the containing units 12 through the holes 111.

The containing units 12 can be disposed in the tray frame 11 so as to contain packaged chips, which are more than the packaged chips in each row of the first containing area E, in each row of the second containing area F.

The number of containing units 12 disposed in the tray frame 11 may be equal to or greater than the number of packaged chips connected to the hi-fix board at a time.

The test tray 1 according to the embodiment of the invention can be classified into three examples depending on the shapes of the packaged chips contained in the containing units 12 in the first containing area E and the second containing area F, which will be sequentially described now with reference to the accompanying drawings.

Referring to FIG. 3, the test tray 1 according to an example includes containing units 12 disposed in the tray frame 11 so as to contain the following shape of packaged chips.

The containing units 12 can be disposed in the tray frame 11 so as to further contain at least one packaged chip in each row of the second containing area F outside the packaged chip S1 located at one end or the packaged chip S2 located at the other end of each row in the first containing area E. That is, in the first containing area E, the packaged chips may not be contained in a predetermined number of containing units 12 at one end or the other end of each row.

The containing units 12 can be disposed in the tray frame 11 so that the number of packaged chips not contained in a row of the first containing area E which includes plural rows is equal to a numerical value obtained by dividing the number of packaged chips not contained in the first containing area by the number of rows of the first containing area. In the area not containing the packaged chips, the containing units 12 may not be disposed and the holes 111 thereof may be empty. Although not shown, the holes 111 may not be formed in the area of the tray frame 11 in which the packaged chips are not contained.

The containing units 12 can be disposed in the tray frame 11 so as to further contain the same number of packaged chips in each row of the second containing area F outside the packaged chip S1 located at one end or the packaged chip S2 located at the other end of each row in the first containing area E.

That is, in the first containing area E, the packaged chips may not be contained in a predetermined number of containing units 12 at one end and the other end of each row.

The containing units 12 can be disposed in the tray frame 11 so that the number of packaged chips not contained in a row of the first containing area E which includes plural rows is equal to a numerical value obtained by dividing the number of packaged chips not contained in the first containing area by the number of rows of the first containing area. In the area not containing the packaged chips, the containing units 12 may not be disposed and the holes 111 thereof may be empty. Although not shown, the holes 111 may not be formed in the area of the tray frame 11 in which the packaged chips are not contained.

When 528 holes 111 are formed in a 22×24 matrix in the tray frame 11, the containing units 12 may be disposed in the tray frame 11 so that two holes 111 are empty at both ends of each row of the first containing area E including four rows are empty. Although not shown, the holes 111 may not be formed in the area of the tray frame 11 in which the packaged chips are not contained.

The containing units 12 may be disposed in the tray frame 11 in the order of the first containing area E, the second containing area F, and the first containing area E from up to down (in the direction of arrow Y) in the tray frame 11.

In this case, the packaged chips may not be contained in the containing units 12 disposed at corners of the tray frame 11. Alternatively, the containing units 12 may be disposed in the tray frame 11 so that the holes 111 are disposed in a rectangular shape at the corners of the tray frame 11.

As shown in FIG. 3, when 528 holes are formed in a 22×24 matrix in the tray frame 11, the containing units 12 can be disposed in the tray frame 11 with four holes 111 empty at each corner of the tray frame 11. That is, the containing units 12 may be arranged in a cross shape. Although not shown, the holes 111 may not be formed in the area of the tray frame 11 in which the containing units 12 are not disposed.

Accordingly, since the containing units 12 can be easily disposed in the tray frame 11 so that the containing units 12 are arranged at proper positions of the tray frame 11, it is possible to easily manufacture the test tray 1.

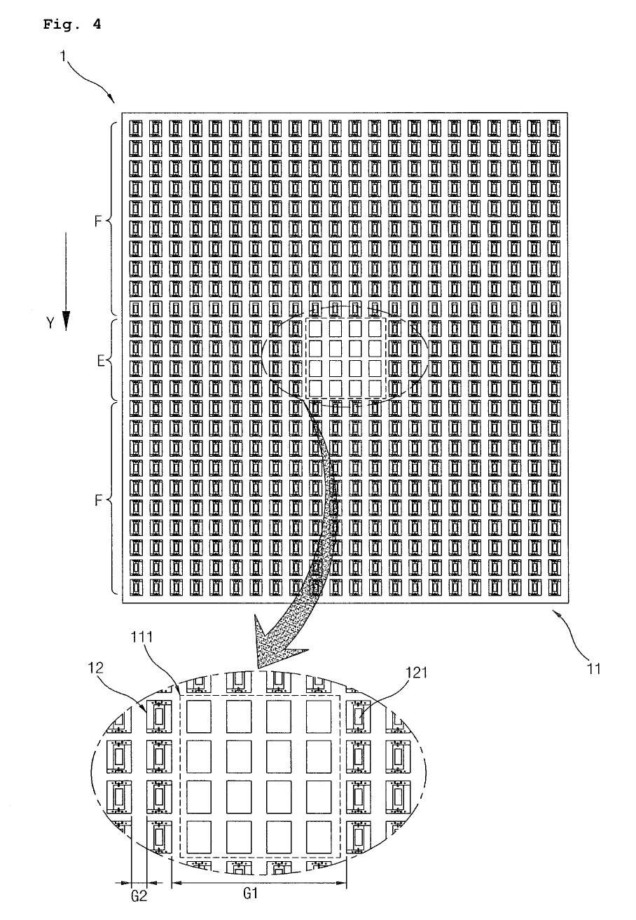

Referring to FIG. 4, the test tray 1 according to another example includes the containing units 12 disposed in the tray frame 11 so as to contain the packaged chips in the following shape.

The containing units 12 can be disposed in the tray frame 11 so that a distance G1 between at least two packaged chips in the first containing area E is greater than a distance G2 between the other packaged chips.

In each row of the first containing area E, predetermined number of containing units 12 between both ends of the row may not contain the packaged chips. The containing units 12 can be disposed in the tray frame 11 so that the number of packaged chips not contained in a row of the first containing area E which includes plural rows is equal to a numerical value obtained by dividing the number of packaged chips not contained in the first containing area by the number of rows of the first containing area.

As shown in FIG. 4, the containing units 12 may not be disposed in the area in which the packaged chips are not contained and the holes 111 thereof may be empty. Although not shown, the holes 111 may not be formed in the area of the tray frame 11 in which the packaged chips are not contained.

As shown in FIG. 4, when 528 holes 111 are formed in a 22×24 matrix in the tray frame 11, the containing units 12 may be disposed in the tray frame 11 with four holes 111 empty in each row of the first containing area E including four rows are empty. Although not shown, the holes 111 may not be formed in the area of the tray frame 11 in which the containing units 12 are not disposed.

The containing units 12 may be disposed in the tray frame 11 in the order of the second containing area F, the first containing area E, and the second containing area F from up to down (in the direction of arrow Y) in the tray frame 11.

In this case, the packaged chips may not be contained in the containing units 12 disposed at the center of the tray frame 11. Alternatively, the containing units 12 may be disposed in the tray frame 11 so that the holes 111 are arranged in a hollow rectangular shape at the center of the tray frame 11.

Accordingly, since the containing units 12 can be easily disposed in the tray frame 11 so that the containing units 12 are arranged at proper positions of the tray frame 11, it is possible to easily manufacture the test tray 1.

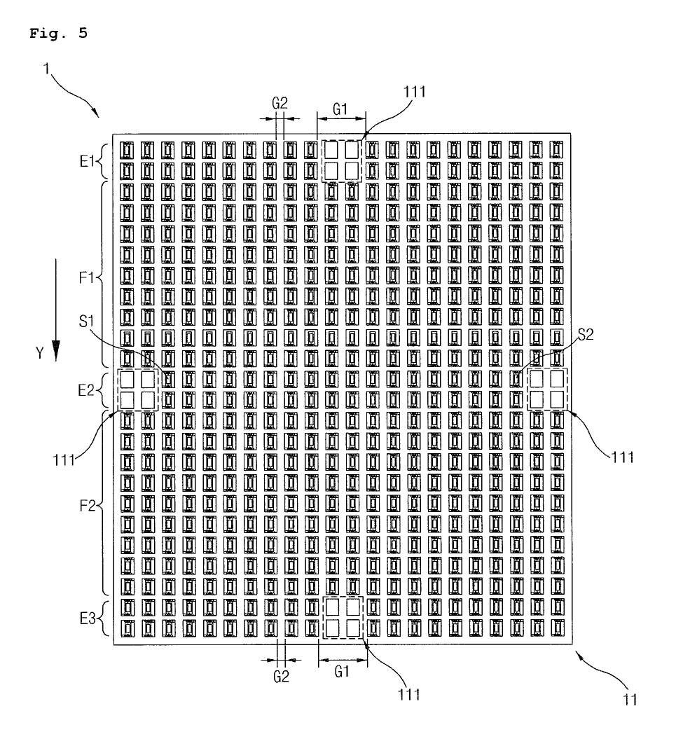

Referring to FIG. 5, the test tray 1 according to another example includes the containing units 12 disposed in the tray frame 11 so as to contain the packaged chips in the shape obtained by combining the above-mentioned examples.

The containing units 12 can be disposed in the order of the first containing area E1, the second containing area F1, the first containing area E2, the second containing area F2, and the first containing area E3 from up to down (in the direction of arrow Y) in the tray frame 11.

In the first containing areas E1 and E3 disposed at the uppermost and the lowermost of the tray frame 11, the containing units 12 are disposed in the tray frame 11 so that the distance G1 between at least two packaged chips is greater than the distance G2 between the other packaged chips.

In each row of the first containing areas E1 and E3, a predetermined number of containing units 12 between both ends of the row may not contain the packaged chips. The containing units 12 can be disposed in the tray frame 11 so that the number of packaged chips not contained in each row of the first containing areas E1 and E3 which includes plural rows is equal to a numerical value obtained by dividing the total number of containing units not containing the packaged chips in the first containing areas by the number of rows of the first containing areas.

As shown in FIG. 5, the containing units 12 may not be disposed in the area in which the packaged chips are not contained and the holes 111 thereof may be empty. Although not shown, the holes 111 may not be formed in the area of the tray frame 11 in which the packaged chips are not contained.

In the first containing areas E1 and E3 located at the uppermost and the lowermost of the tray frame 11, the containing units 12 can be disposed in the tray frame 11 to correspond to each other.

The containing units 12 can be disposed in the tray frame 11 so as to further contain the same number of packaged chips in each row of the second containing areas F1 and F2 located in the upside and the downside of the tray frame 11 outside the packaged chip S1 located at one end or the packaged chip S2 located at the other end of each row in the first containing area E2 between.

That is, in each row of the first containing area E2, the packaged chips may not be contained in a predetermined number of containing units 12 at one end and the other end of each row.

The containing units 12 can be disposed in the tray frame 11 so that the number of packaged chips not contained in each row of the first containing area E2 which includes plural rows is equal to a numerical value obtained by dividing the total number of packaged chips not contained in the first containing area by the number of rows of the first containing area.

In the area not containing the packaged chips, the containing units 12 may not be disposed and the holes 111 thereof may be empty. Although not shown, the holes 111 may not be formed in the area of the tray frame 11 in which the packaged chips are not contained.

As shown in FIG. 5, when 528 holes 111 are formed in a 22×24 matrix in the tray frame 11, the containing units 12 may be disposed in the tray frame 11 so as to contain the packaged chips in the following shape.

Each of the first containing areas E1 and E3 located at the uppermost and the lowermost of the tray frame 11 includes two rows and two packaged chips are not contained between both ends of each row. In this case, the containing units 12 can be disposed in the tray frame 11 with two holes 111 empty between both ends of each row.

The first containing area E2 located between the second containing areas F1 and F2 contains two rows and two packaged chips are not contained at both ends of each row. In this case, the containing units 12 may be disposed in the tray frame 11 with two holes 111 empty at both ends of each row.

The packaged chips are contained in each row of the second containing areas B1 and B2. In this case, the containing units 12 can be disposed in the tray frame 11 to correspond to the number of holes 111.

Accordingly, since eight packaged chips in total are not contained in the first containing areas E1 and E3 and eight packaged chips are not contained in the first containing area E2, 512 packaged chips in total can be contained in the test tray 1.

In this case, since eight holes 111 in total are empty in the first containing areas E1 and E3 and eight holes 111 are empty in the first containing area E2, 512 containing units in total can be disposed in the tray frame 11.

Accordingly, it is possible to easily manufacture the test tray 1 according to the embodiment of the invention while minimizing the difference between the length 1L in the horizontal direction (see FIG. 3) and the length 1H in the vertical direction (see FIG. 3).

A hi-fix board according to an exemplary embodiment of the invention will be described now in detail with reference to the accompanying drawings.

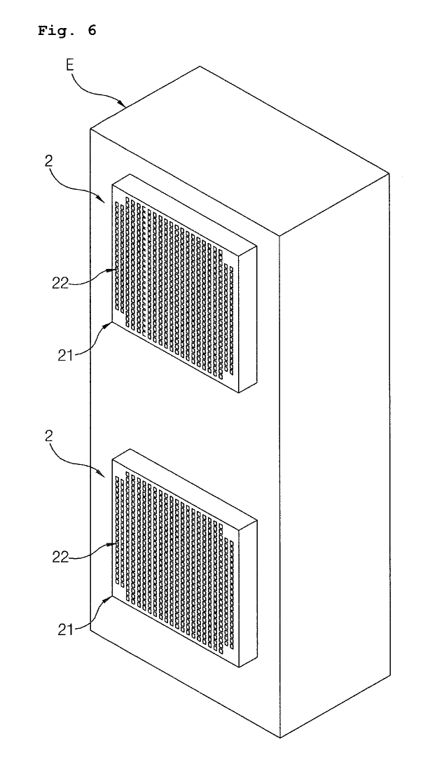

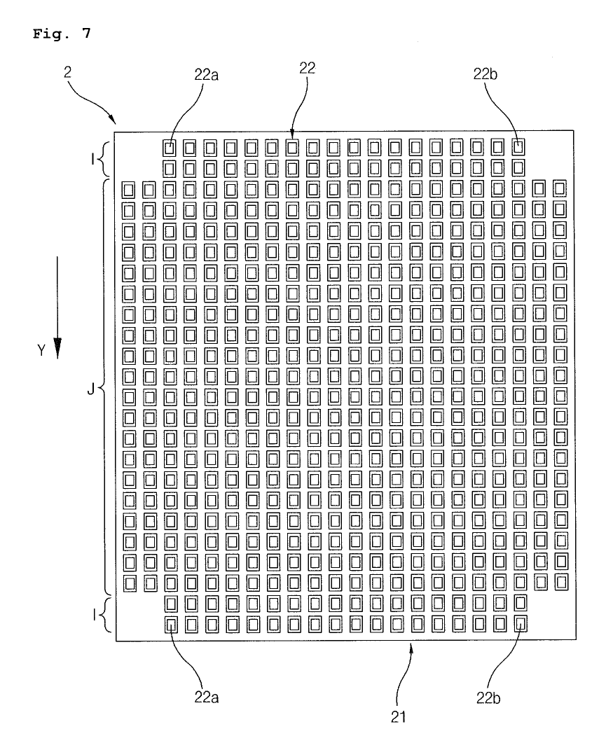

FIG. 6 is a perspective schematically illustrating a tester and a hi-fix board disposed therein according to the embodiment of the invention. FIGS. 7 to 9 are front views schematically illustrating modified examples of the hi-fix board according to the embodiment of the invention.

Referring to FIG. 6, the hi-fix board 2 includes a main frame 21 and test sockets 22.

The main frame 21 is provided with plural test sockets 22 and connects the test sockets 22 to a tester E. The tester E tests the packaged chips to determine electrical characteristics of the packaged chips connected to the test sockets 22.

Plural hi-fix boards 2 may be disposed in the tester E. Two hi-fix boards 2 can be stacked in the tester E and the packaged chips contained in one test tray 1 can be connected to each hi-fix board 2. That is, when 512 packaged chips are contained in the test tray 1, the tester E can test 1024 packaged chips at a time.

Referring to FIGS. 6 and 7, plural test sockets 22 are disposed in at least one first area I of the main frame 21 to form an a×b matrix (where a and b are integers greater than 0) and plural test sockets are disposed in at least one second area J to form a c×d matrix (where c is an integer greater than a and d is an integer greater than 0).

In the hi-fix board 2, the test sockets 22 can be disposed in the main frame 21 to form different matrixes in the first area I and the second area J so as to minimize the difference between the length 1L in the horizontal direction (see FIG. 3) and the length 1H in the vertical direction of the test tray 1 (see FIG. 3).

Accordingly, it is possible to solve the problem that the test tray T (see FIG. 1) according to the related art is formed longitudinal in one direction of the horizontal direction L (see FIG. 1) and the vertical direction H (see FIG. 1) due to containing the packaged chips to form one matrix.

An area of the main frame 12 in which the test sockets 22 can be disposed can be formed in a c×(b+d) matrix. The c×(b+d) matrix may be one of a 22×24 matrix, a 24×22 matrix, a 20×26 matrix, a 26×20 matrix, and a 23×23 matrix. In this area, 512 test sockets 22 can be disposed in the main frame 21.

As shown in FIG. 7, when the areas in which the test sockets 22 can be disposed form a 22×24 matrix in the main frame 21, only 512 test sockets 22 can be disposed. Accordingly, the test sockets 22 may not be disposed in the area in which 16 test sockets 22 can be disposed among the area of the main frame 21 in which 528 test sockets 22 in total can be disposed. The same is true when the area of the main frame 21 in which the test sockets 22 can be disposed is formed in a 24×22 matrix.

Although not shown, when the area of the main frame 21 in which the test sockets 22 can be disposed is formed in the 20×26 matrix or a 26×20 matrix, only 512 test sockets 22 can be disposed. Accordingly, the test sockets 22 may not be disposed in the area in which 8 test sockets 22 can be disposed among the area of the main frame 21 in which 520 test sockets 22 in total can be disposed.

Although not shown, when the area of the main frame 21 in which the test sockets 22 can be disposed is formed in the 23×23 matrix, only 512 test sockets 22 can be disposed. Accordingly, the test sockets 22 may not be disposed in the area in which 17 test sockets 22 can be disposed among the area of the main frame 21 in which 529 test sockets 22 in total can be disposed.

Accordingly, the hi-fix board 2 according to the embodiment of the invention can be embodied to connect 512 packaged chips while minimizing the difference between the length 1L in the horizontal direction (see FIG. 3) and the length 1H in the vertical direction (see FIG. 3) of the test tray 1 (see FIG. 3).

Referring to FIGS. 6 and 7, the test sockets 22 are connected to the packaged chips to be tested and are disposed in the main frame 21 at positions for connection to the packaged chips to be tested in the test tray 1 (see FIG. 3). That is, in the main frame 21, the test sockets 22 are not disposed at the positions corresponding to the positions of the test tray 1 (see FIG. 3) in which the packaged chips are not contained.

The test sockets 22 can be disposed in the main frame 21 so that the number of test sockets in each row of the second area J is greater than the number of test sockets in each row of the first area I. The test sockets 22 can be disposed in the main frame 21 so that the number of test sockets is equal to the number of packaged chips connected thereto.

The hi-fix board 2 according to the embodiment of the invention can be classified into three examples depending on the disposal shapes of the test sockets 22, which will be sequentially described now with reference to the accompanying drawings.

Referring to FIG. 7, the hi-fix board 2 according to an example includes test sockets 22 disposed in the main frame 21 in the following shape.

In the main frame 21, at least one test socket 22 may be further disposed in each row of the second area J outside the test socket 22a located at one end or the test socket 22b located at the other end of each row in the first area I. That is, a predetermined number of test sockets 22 may not be disposed in the main frame at one end or the other end of each row in the first area I.

The test sockets 22 can be disposed in the main frame 21 so that the number of test sockets 22 not disposed in each row of the first area I which includes plural rows is equal to a numerical value obtained by dividing the number of test sockets not disposed in the first area by the number of rows of the first area.

In the main frame 21, the same number of test sockets 22 may further be disposed in each row of the second area J outside the test socket 22a located at one end or the test socket 22b located at the other end of each row in the first area I. That is, the same number of test sockets 22 may not be disposed in each row of the first area I of the main frame 21 at one end and the other end of each row.

The test sockets 22 can be disposed in the main frame 21 so that the number of test sockets 22 not disposed at both ends of each row of the first area I including plural rows is equal to a numerical value obtained by dividing the total number of test sockets not disposed in the first area by the number of rows of the first area.

When 528 areas in which the test sockets 22 can be disposed form a 22×24 matrix in the main frame 21, two test sockets 22 may not be disposed at both ends of each row of the first area I including four rows.

The test sockets 22 may be disposed in the main frame 21 in the order of the first area I, the second area J, and the first area I from up to down (in the direction of arrow Y) in the main frame 21. In this case, the test sockets 21 may not be disposed at corners of the main frame 21.

As shown in FIG. 7, when 528 areas in which the test sockets 22 can be disposed form a 22×24 matrix in the main frame 21, four test sockets 22 may not be disposed at each corner of the main frame 21. That is, the test sockets 22 may be arranged in a cross shape.

Accordingly, since the test sockets 22 can be easily disposed in the main frame 21 so that the test sockets 22 are arranged at proper positions of the main frame 21, it is possible to easily manufacture the hi-fix board 2.

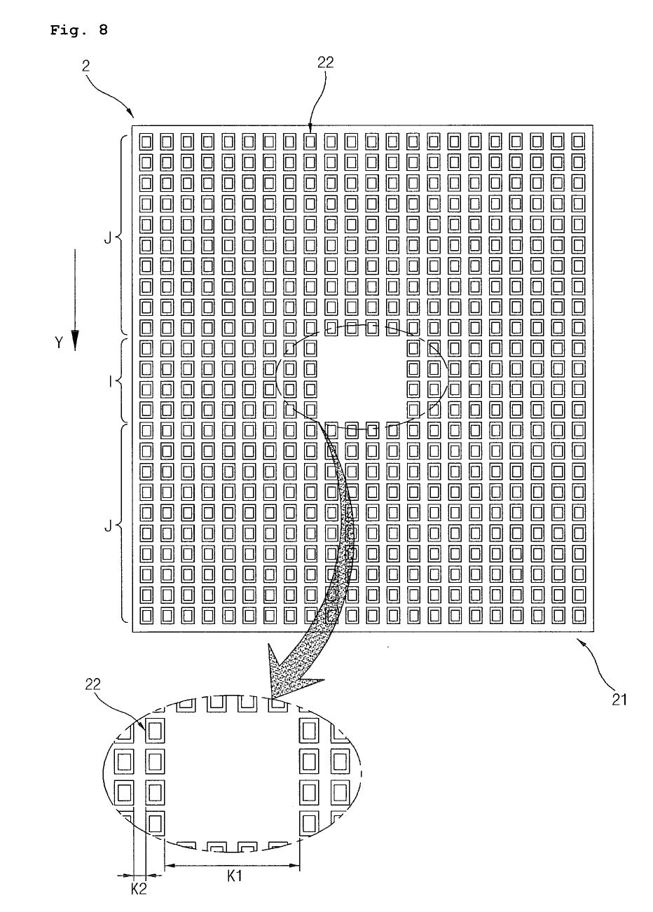

Referring to FIG. 8, a hi-fix board according to another example includes test sockets 22 disposed in the main frame 21 in the following shape.

The test sockets 22 can be disposed in the main frame 21 so that the distance K1 between at least two test sockets 22 in the first area I is greater than the distance K2 between the other test sockets.

In each row of the first area I, a predetermined number of test sockets 22 may not be disposed between both ends of each row. The test sockets 22 can be disposed in the main frame 21 so that the number of test sockets 22 not disposed in each row of the first area I which includes plural rows is equal to a numerical value obtained by dividing the total number of test sockets not disposed in the first area by the number of rows of the first area.

When 528 areas in which the test sockets 22 can be disposed form a 22×24 matrix in the main frame 21, four test sockets 22 may not be disposed between both ends of each row of the first area I including four rows.

The test sockets 22 can be disposed in the main frame 21 in the order of the second area J, the first area I, and the second area J from up and down (in the direction of arrow Y) in the main frame 21. In this case, the test sockets 22 may not be disposed at the center of the main frame 21.

As shown in FIG. 8, when 528 areas in which the test sockets 22 can be disposed form a 22×24 matrix in the main frame 21, sixteen test sockets 22 may not be disposed at the center of the main frame 21. That is, the test sockets 22 may be arranged in a hollow rectangular shape.

Accordingly, since the test sockets 22 can be easily disposed in the main frame 21 so that the test sockets 22 are arranged at proper positions of the main frame 21, it is possible to easily manufacture the hi-fix board 2.

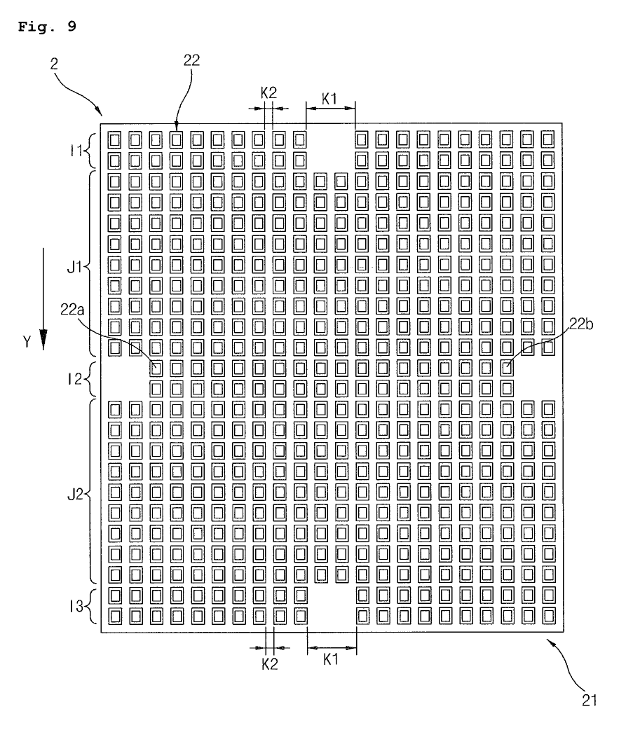

Referring to FIG. 9, the hi-fix board 2 according to another example includes test sockets 22 disposed in the main frame 21 in a shape obtained by combining the above-mentioned examples.

The test sockets 22 can be disposed in the order of the fist area I1, the second area J1, the first area I2, the second area J2, and the first area I3 from up to down (in the direction of arrow Y) in the main frame 21.

In the first areas I1 and I3 located at the uppermost and the lowermost of the main frame 21, the test sockets are disposed in the main frame 21 so that the distance K1 between at least two test sockets is greater than the distance K2 between the other test sockets 22.

In each row of the first areas I1 and I3 of the main frame 21, a predetermined number of test sockets 22 may not be disposed between both ends of each row. The test sockets 22 can be disposed in the main frame 21 so that the number of test sockets 22 not disposed in each row of the first areas I1 and I3 which includes plural rows is equal to a numerical value obtained by dividing the total number of test sockets not disposed in the first areas by the number of rows of the first areas.

In the first areas I1 and I3 located at the uppermost and the lowermost of the main frame 21, the test sockets 22 are disposed in the main frame 21 to correspond to each other in shape.

In each row of the second areas J1 and J2 located in the upside and the downside of the main frame 21, the same number of test sockets may be further disposed outside the test socket 22a located at one end and the test socket 22b located at the other end of each row of the first area I2 located therebetween.

The numbers of test sockets 22 not disposed at one end of the other end of each row of the first area I2 in the main frame 21 may be equal to each other.

The test sockets 22 may be disposed in the main frame 21 so that the number of test sockets not disposed in each row of the first area I2 including plural rows is equal to a numerical value obtained by dividing the total number of test sockets not disposed in the first area by the number of rows of the first area.

As shown in FIG. 9, when 528 areas in which the test sockets 22 can be disposed form a 22×24 matrix in the main frame 21, the test sockets 22 may be disposed in the main frame 21 in the following shape.

Each of the first areas I1 and I3 located at the uppermost and the lowermost of the main frame 21 includes two rows and two test sockets 22 are not disposed in the main frame 21 between both ends of each row.

The first area I2 located between the second areas J1 and J2 includes two rows and the test sockets 22 are not disposed at both ends of each row in the main frame 21.

The test sockets 22 are disposed in each row of the second areas J1 and J2.

Accordingly, since four test sockets 22 are not disposed in each of the first areas I1 and I3 of the main frame 21 and eight test sockets 22 are not disposed in the first area I2 of the main frame 21, 512 test sockets in total can be disposed in the main frame 21.

Accordingly, it is possible to easily manufacture the hi-fix board 2 according to the embodiment of the invention while minimizing the difference between the length 1L in the horizontal direction (see FIG. 3) and the length 1H in the vertical direction (see FIG. 3) of the test tray 1 (see FIG. 3).

A test handler according to an exemplary embodiment of the invention will be described now in detail with reference to the accompanying drawings. Since the test handler performs a loading process, an unloading process, and a testing process by the use of the above-mentioned test tray, the detailed description of the test tray is omitted not to make the gist of the invention vague.

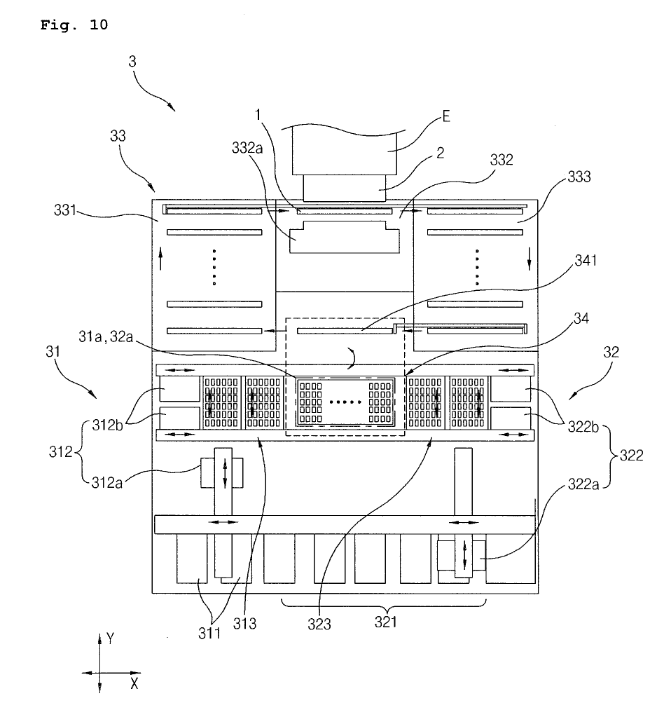

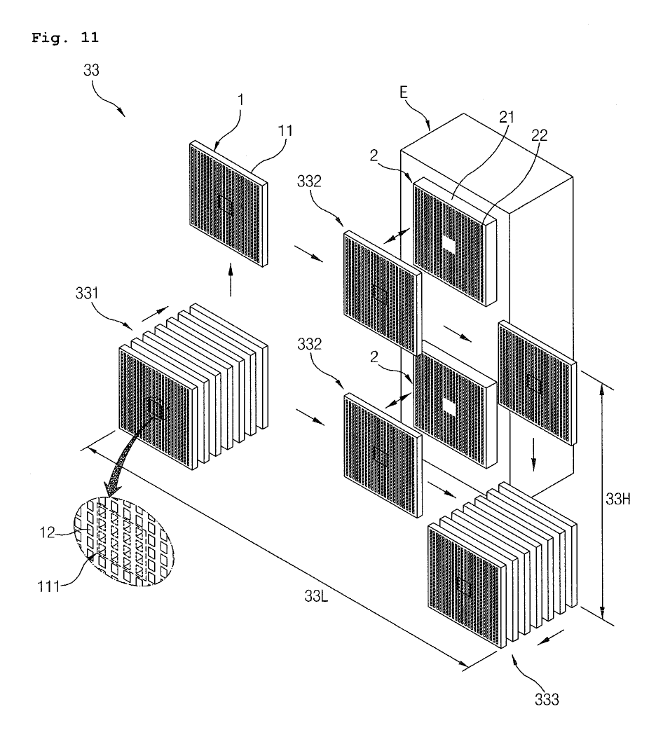

FIG. 10 is a plan view schematically illustrating a test handler according to an embodiment of the invention. FIG. 11 is a diagram schematically illustrating a hi-fix board and a path through which the test tray is transferred in the chamber system of the test handler according to the embodiment of the invention.

Referring to FIG. 10, the test handler 3 includes a loading unit 31, an unloading unit 32, a chamber system 33, and a transferring unit (not shown).

The loading unit 31 performs a loading process and includes a loading stacker 311, a loading picker 312, and a loading buffer 313.

The loading stacker 311 stores plural user trays containing packaged chips to be tested.

The loading picker 312 transfers the packaged chips from the user tray located in the loading stacker 311 to a test tray 1 located at a loading position 31a. The loading picker 312 includes nozzles sucking and fixing the packaged chips and can move in the X axis direction and the Y axis direction and move up and down.

The loading picker 312 may include a first loading picker 312a and a second loading picker 312b.

The first loading picker 312a picks up the packaged chips to be tested from the user tray located in the loading stacker 311 and stores the picked-up packaged chips in the loading buffer 313.

The second loading picker 312b picks up the packaged chips to be tested stored in the loading buffer 313 and contains the picked-up packaged chips in the test tray 1 located at the loading position 31a. The loading picker 312 may include plural first loading pickers 312a and plural second loading pickers 312b.

The loading buffer 313 temporarily stores the packaged chips to be tested. The loading buffer 313 can move in the Y axis direction and the number of loading buffers may be two or more.

The unloading unit 32 performs an unloading process and can be disposed aside the loading unit 31. The unloading unit 32 includes an unloading stacker 321, an unloading picker 322, and an unloading buffer 323.

The unloading stacker 321 stores plural user trays containing the tested packaged chips. The tested packaged chips are contained in the user trays located at different positions in the unloading stacker 321 by grades on the basis of the test result.

The unloading picker 322 separates the tested packaged chips from the test tray 1 located at an unloading position 32a and contains the separated packaged chips in the user trays located in the unloading stacker 321. The unloading picker 322 includes nozzles sucking and fixing the packaged chips and can move in the X axis direction and the Y axis direction and move up and down.

The unloading picker 322 may include a first unloading picker 322a and a second unloading picker 322b.

The first unloading picker 322a picks up the tested packaged chips stored in the unloading buffer 323 and contains the picked-up packaged chips in the user trays located in the unloading stacker 321. The first unloading picker 322a can contain the tested packaged chips in the user trays located at different positions in the unloading stacker 321 by grades on the basis of the test result.

The second unloading picker 322b separates the tested packaged chips from the test tray 1 located at the unloading position 32a and stores the separated packaged chips in the unloading buffer 323.

The unloading picker 322 may includes plural first unloading pickers 322a and plural second unloading pickers 322b.

The unloading buffer 323 temporarily stores the tested packaged chips. The unloading buffer 323 can move in the Y axis direction and the number of unloading buffers may be two or more.

Here, in the test handler 3, the loading position 31a and the unloading position 32a can be embodied in the same area. In this case, the loading position 31a and the unloading position 32a may be embodied by an exchanging unit 34. The exchanging unit 34 can be disposed between the loading unit 31 and the unloading unit 32. The exchanging unit 34 may include a rotating unit 341 rotating the test tray 1.

The rotating unit 341 rotates the test tray 1 containing the packaged chips to be tested from a horizontal posture to a vertical posture. The rotating unit 341 rotates the test tray 1 containing the tested packaged chips from the vertical posture to the horizontal posture. Accordingly, the test handler 3 can perform the loading process and the unloading process on the test tray 1 with the horizontal posture and can perform the testing process on the test tray 1 with the vertical posture.

Although not shown, the loading position 31a and the unloading position 32a in the test handler 3 can be embodied in different areas. In this case, the loading position 31a can be embodied by a first exchanging unit (not shown) and the unloading position 32a can be embodied by a second exchanging unit (not shown).

The first exchanging unit is disposed at a position close to the loading unit 31 and the second exchanging unit is disposed at a position close to the unloading unit 32. The first exchanging unit may include a first rotating unit (not shown) rotating the test tray 1 containing the packaged chips to be tested and the second exchanging unit may include a second rotating unit (not shown) rotating the test tray 1 containing the tested packaged chips.

Referring to FIGS. 10 and 11, the chamber system 33 includes a first chamber 331, a second chamber 332, and a third chamber 333 so as for the tester to test packaged chips under environments of high temperature and low temperature as well as normal temperature.

The test tray 1 transferred in the chamber system 33 can be manufactured with the minimized difference between the length 1L in the horizontal direction (see FIG. 3) and the length 1H in the vertical direction (see FIG. 3) as described above.

Accordingly, even when the test tray 1 is improved to contain more packaged chips, the chamber system 33 can increase in size without being inclined in one of the horizontal direction 33L and the vertical direction 33H.

Therefore, even when the test tray 1 is embodied to contain more packaged chips so as to reduce the time for the testing process, the test handler 3 according to the embodiment of the invention can satisfy the standard determined depending on the installation area.

In the test handler 3 according to the embodiment of the invention, since the test tray 1 does not increase in size in the horizontal direction (see FIG. 3), it is possible to suppress the increase in moving distance of the test tray 1. Accordingly, it is possible to reduce the index time and to greatly reduce the time for the testing process. Since the wait time of the test tray 1 in the loading process and the unloading process can be reduced with the reduction in time for the testing process, it is possible to reduce the entire process time of the test handler 3.

Referring to FIGS. 10 and 11, the first chamber 331 adjusts the packaged chips to be tested contained in the test tray 1 to the testing temperature. The test tray 1 containing the packaged chips to be tested is a test tray 1 transferred from the loading position 31a. That is, the test tray 1 containing the packaged chips to be tested is a test tray 1 transferred from the exchanging unit 34 or the first exchanging unit to the first chamber 331.

The first chamber 331 may be provided with at least one of an electric heater and a liquefied nitrogen injecting apparatus to adjust the packaged chips to be tested to the testing temperature. The first chamber 331 can allow the test tray 1 with the vertical posture to move therein.

When the packaged chips to be tested are adjusted to the testing temperature, the test tray 1 is transferred from the first chamber 331 to the second chamber 332.

The second chamber 332 connects the packaged chips adjusted to the testing temperature and contained in the test tray 1 to the hi-fix board 2. The second chamber 332 is provided with a contact unit 332a connecting the packaged chips adjusted to the testing temperature to the hi-fix board 2, where a part or all of the hi-fix board 2 is inserted into the contact unit. The tester E tests the packaged chips to determined electrical characteristics of the packaged chips connected to the hi-fix board 2.

In the hi-fix board 2 disposed in the second chamber 332, the test sockets 22 can be disposed in the main frame 21 to form a matrix corresponding to the holes 111.

In the hi-fix board 2 disposed in the second chamber 332, the test sockets 22 can be disposed in the main frame 21 at positions for connection to the packaged chips adjusted to the testing temperature and contained in the test tray 1. Since the hi-fix board 2 is the same as described above, the detailed description thereof is omitted so as not to make the gist of the invention vague

The second chamber 332 may be provided with at least one of an electric heater and a liquefied nitrogen injecting apparatus to maintain the packaged chips to be tested at the testing temperature. The test handler 3 may include plural second chambers 332 and the hi-fix board 2 may be disposed in each of the second chambers 332.

When the packaged chips are completely subjected to the testing process, the test tray 1 is transferred from the second chamber 332 to the third chamber 33.

The third chamber 33 restores the tested packaged chips contained in the test tray 1 to the normal temperature. The third chamber 333 may be provided with at least one of an electric heater and a liquefied nitrogen injecting apparatus to restore the tested packaged chips to the normal temperature. The third chamber 333 can allow the test tray 1 with the vertical posture to move therein.

When the tested packaged chips are restored to the normal temperature or a temperature close to the normal temperature, the test tray 1 is transferred from the third chamber 333 to the unloading position 32a. That is, the test tray 1 can be transferred from the third chamber 333 to the exchanging unit 34 or the second exchanging unit.

As shown in FIG. 10, in the chamber system 33, the first chamber 331, the second chamber 332, and the third chamber 333 may be disposed in the horizontal direction. Plural second chambers 332 may be stacked.

The transferring unit transfers the test tray 1 among the loading position 31a, the chamber system 33, and the unloading position 32a. The transferring unit can be actuated by a transferring means employing an actuator, a pulley, and a belt and can transfer the test tray by pushing or pulling the test tray 1.

The transferring unit can transfer the test tray 1 to the loading position 31a, the first chamber 331, the second chamber 332, the third chamber 333, and the unloading position 32a. When the loading position 31a and the unloading position 32a are embodied in different areas, the transferring unit can transfer the test tray 1 having been subjected to the unloading process and being made to be empty from the unloading position 32a to the loading position 31a. That is, the test tray 1 can be circulated in the test handler 3.

A packaged chip manufacturing method according to an exemplary embodiment of the invention will be described now in detail with reference to the accompanying drawings.

Referring to FIGS. 10 and 11, the packaged chip manufacturing method includes the following elements.

First, packaged chips to be tested are prepared. This step may include containing the packaged chips to be tested in a user tray and storing the user tray in the loading stacker 311. The packaged chips include memory or non-memory packaged chips.

The, the prepared packaged chips to be tested are contained in the test tray 1 located at the loading position 31a.

This step can include allowing the loading picker 312 to contain the prepared packaged chips from the user tray located in the loading stacker 311 to the test tray 1 located at the loading position 31a through the loading buffer 313.

In the test tray 1, as described above, the number of containing units 12 disposed in the tray frame 11 is equal to or greater than the number of packaged chips to be tested.

Then, the packaged chips to be tested in the test tray 1 are adjusted to the testing temperature.

This step can include allowing the first chamber 331 to adjust the packaged chips to be tested to the testing temperature while allowing the test tray 1 transferred from the loading position 31a by the transferring unit to move therein.

The test tray 1 containing the packaged chips adjusted to the testing temperature is transferred from the first chamber 331 to the second chamber 332 by the transferring unit.

The packaged chips contained in the test tray 1 and adjusted to the testing temperature are connected to the hi-fix board 2.

This step can include allowing the second chamber 332 to connect the packaged chips contained in the test tray 1 and adjusted to the testing temperature to the hi-fix board 2. In the hi-fix board 2, the test sockets 22 are disposed in the main frame 21 at the positions for connection to the packaged chips contained in the test tray 1.

When the packaged chips are completely tested, the test tray 1 is transferred from the second chamber 332 to the third chamber 333 by the transferring unit.

Then, the tested packaged chips contained in the test tray 1 are restored to the normal temperature.

This step can include allowing the third chamber 333 to restore the tested packaged chips to the normal temperature while allowing the test tray 1 to move therein.

When the tested packaged chips are restored to the normal temperature or a temperature close to the normal temperature, the test tray 1 is transferred from the third chamber 333 to the unloading position 32a by the transferring unit.

Then, the tested packaged chips contained in the test tray 1 located at the unloading position 32a are classified on the basis of the test result.

This step can include allowing the unloading picker 322 to separate the tested packaged chips from the test tray 1 located at the unloading position 32a and then to contain the separated packaged chips in the user tray located in the unloading stacker 321 through the unloading buffer 323. The unloading picker 322 can contain the tested packaged chips in the user trays located at different positions in the unloading stacker 321 by grades on the basis of the test result.

When the unloading position 32a and the loading position 31a are embodied in different areas, the test tray 1 having been subjected to the unloading process and made to be empty can be transferred from the unloading position 32a to the loading position 31a by the transferring unit.

By repeatedly performing the above-mentioned processes, it is possible to complete the manufacturing of the packaged chips.

The invention is not limited to the above-mentioned embodiments and the accompanying drawings, but it will be clearly understood by those skilled in the art that the embodiments can be modified in various forms without departing from the technical idea of the invention.

What is claimed is:

1. A hi-fix board comprising:
test sockets to which packaged chips to be tested are connected; and
a main frame in which the test sockets are disposed in at least one first area to form an a×b matrix (where a and b are integers greater than 0) and the test sockets are disposed in at least one second area to form a c×d matrix (where c is an integer greater than a and d is an integer greater than 0).

2. The hi-fix board according to claim 1, wherein a c×(b+d) matrix is one of a 22×24 matrix, a 24×22 matrix, a 20×26 matrix, a 26×20 matrix, and a 23×23 matrix and 512 test sockets are arranged in the main frame.

3. A hi-fix board comprising:
test sockets to which packaged chips to be tested are connected; and
a main frame in which the test sockets are arranged in a first area including at least one row and a second area including the other rows,
wherein the number of test sockets disposed in each row of the second area in the main frame is greater than the number of test sockets in each row of the first area.

4. The hi-fix board according to claim 3, wherein the test sockets are disposed in the main frame so that a distance between at least two test sockets is greater than a distance between the other test sockets in the first area of the main frame.

5. The hi-fix board according to claim 4, wherein the test sockets are disposed in the order of the second area, the first area, and the second area from up to down in the main frame.

6. The hi-fix board according to claim 3, wherein at least one test socket is further disposed in each row of the second area outside the test socket located at one end or the test socket located at the other end in each row of the first area.

7. The hi-fix board according to claim 3, wherein the same number of test sockets is further disposed in each row of the second area outside the test sockets located at one end and the test socket located at the other end in each row of the first area.

8. The hi-fix board according to claim 7, wherein the test sockets are disposed in the order of the first area, the second area, and the first area from up to down in the main frame.

9. The hi-fix board according to claim 3, wherein the test sockets are disposed in the order of the first area, the second area, the first area, and the second area, and the first area from up to down in the main frame,
wherein the test sockets are disposed in the main frame so that a distance between at least two test sockets is greater than a distance between the other test sockets in the first areas located at the uppermost and the lower most of the main frame, and
wherein the same number of test sockets is further disposed in each row of the second areas in the upside and the downside of the main frame outside the test sockets located at one end and the test socket located at the other end in each row of the first area therebetween.

10. A test tray comprising:
containing units containing packaged chips; and
a tray frame in which the containing units are disposed in at least one first containing area to contain the packaged chips in an a×b (where a and b are integers greater than 0) matrix and are disposed in at least one second containing area to contain the packaged chips in an c×d (where d is an integer greater than a and d is an integer greater than 0) matrix.

11. The test tray according to claim 10, wherein a c×(b+d) matrix is one of a 22×24 matrix, a 24×22 matrix, a 20×26 matrix, a 26×20 matrix, and a 23×23 matrix and the containing units are disposed in the tray frame to contain 512 test sockets.

12. The test tray according to claim 10, wherein a plurality of holes forming a c×(b+d) matrix are formed in the tray frame.

13. A test tray comprising:
containing units containing packaged chips; and
a tray frame in which the containing units are disposed in a first containing area forming at least one row and in a second containing area forming the other rows,
wherein the containing units are disposed in the tray frame so as to contain the packaged chips, which are more than the packaged chips in each row of the first containing area, in each row of the second containing area.

14. The test tray according to claim 13, wherein the containing units are disposed in the first containing area of the tray frame so that a distance between at least two packaged chips is greater than a distance between the other packaged chips.

15. The test tray according to claim 14, wherein the containing units are disposed in the tray frame in the order of the second containing area, the first containing area, and the second containing area from up to down in the tray frame.

16. The test tray according to claim 13, wherein the containing units are disposed in the tray frame so as to further contain at least one packaged chip in each row of the second containing area outside the packaged chip located at one end or the packaged chip located at the other end in each row of the first containing area.

17. The test tray according to claim 13, wherein the containing units are disposed in the tray frame so as to further contain the same number of packaged chips in each row of the second containing area outside the packaged chip located at one end and the packaged chip located at the other end in each row of the first containing area.

18. The test tray according to claim 17, wherein the containing units are disposed in the tray frame in the order of the first containing area, the second containing area, and the first containing area from up to down in the tray frame.

19. The test tray according to claim 13, wherein the containing units are disposed in the order of the first containing area, the second containing area, the first containing area, and the second containing area, and the first containing area from up to down in the tray frame,
wherein the containing units are disposed in the tray frame so that a distance between at least two packaged chips is greater than a distance between the other packaged chips in the first containing areas located at the uppermost and the lower most of the tray frame, and
wherein the containing units are disposed in the tray frame so as to further contain the same number of packaged chips in each row of the second areas located in the upside and the downside of the tray frame outside from the packaged chip located at one end and the packaged chip located at the other end in each row of the first containing area therebetween.

20. A test handler comprising:
a test tray including containing units containing packaged chips and a tray frame in which the containing units are disposed in at least one first containing area to contain the packaged chips in an a×b (where a and b are integers greater than 0) matrix and are disposed in at least one second containing area to contain the packaged chips in an c×d (where d is an integer greater than a and d is an integer greater than 0) matrix;
a loading unit containing the packaged chips to be tested in the test tray located in a loading position;
a chamber system adjusting the packaged chips to be tested in the test tray to a testing temperature, connecting the packaged chips adjusted to the testing temperature to a hi-fix board, and restoring the tested packaged chips to a normal temperature;
an unloading unit disposed aside the loading unit so as to classify the tested packaged chips contained in the test tray located in an unloading position on the basis of the test result; and
a transferring unit transferring the test tray among the loading position, the chamber system, and the unloading position.

21. The test handler according to claim 20, wherein the hi-fix board includes a plurality of test sockets disposed at positions for connection to the packaged chips contained in the test tray and adjusted to the testing temperature.

22. A packaged chip manufacturing method comprising the steps of:
preparing packaged chips to be tested;
containing the prepared packaged chips in a test tray located at a loading position;
adjusting the packaged chips contained in the test tray to a testing temperature;
connecting the packaged chips contained in the test tray and adjusted to the testing temperature to a hi-fix board;
restoring the tested packaged chips contained in the test tray to a normal temperature; and
classifying the tested packaged chips contained in the test tray located at an unloading position on the basis of the test result,
wherein the test tray includes containing units containing the packaged chips and a tray frame in which the containing units are disposed in at least one first containing area to contain the packaged chips in an a×b (where a and b are integers greater than 0) matrix and are disposed in at least one second containing area to contain the packaged chips in an c×d (where d is an integer greater than a and d is an integer greater than 0) matrix.

23. The method according to claim 22, wherein the step of connecting the packaged chips contained in the test tray and adjusted to the testing temperature to a hi-fix board includes connecting the packaged chips adjusted to the testing temperature to the hi-fix board in which a plurality of test sockets are disposed at positions for connection to the packaged chips contained in the test tray and adjusted to the testing temperature.
